(19) United States
(12) Patent Application Publication
(10) Pub. No.: US 2018/0088387 A1
(43) Pub. Date: Mar. 29, 2018

(54) ELECTROOPTICAL DEVICE AND ELECTRONIC APPARATUS

(71) Applicant: SEIKO EPSON CORPORATION, Tokyo (JP)

(72) Inventor: Shinta ENAMI, Matsumoto-shi (JP)

(73) Assignee: SEIKO EPSON CORPORATION, Tokyo (JP)

(21) Appl. No.: 15/696,802

(22) Filed: Sep. 6, 2017

(30) Foreign Application Priority Data
Sep. 29, 2016 (JP) 2016-190775

(51) Int. Cl. G02F 1/1345; H05K 1/11; H05K 1/18

(52) U.S. Cl. CPC G02F 1/13452; H05K 1/111; H05K 1/189; G02F 1/137; G02F 1/13458; H05K 2201/10136; H05K 1/118

(57) ABSTRACT

Provided an electro-optical device including: an electro-optical panel; a flexible board connected to the electro-optical panel; and an integrated circuit adhered on the flexible board, in which the flexible board includes a wiring, a first connection terminal group connected to control signal terminals of the integrated circuit, and a second connection terminal group including power supply connection terminals connected to a power supply terminal of the integrated circuit, in which the flexible board includes planar patterns connected to the power supply connection terminals, and in which the integrated circuit includes a wiring layer connected to the power supply connection terminals and facing the planar patterns.

### BACKGROUND

### 1. Technical Field

The present invention relates to an electro-optical device and an electronic apparatus including the electro-optical device.

### 2. Related Art

Electro-optical devices for displaying an image using liquid crystal elements have been widely developed. In the electro-optical device, by supplying a voltage according to designated gradation of each pixel to each pixel via a data line, and controlling transmittance of a liquid crystal included in each pixel to transmittance according to the designated gradation, the designated gradation is displayed on each pixel.

On the other hand, in a method of driving a liquid crystal panel by using a driving circuit incorporated in the liquid crystal panel in which the pixels are arrayed and a driver IC which is a driving circuit provided on a flexible printed circuit board, as resolution of the liquid crystal panel is increased, improvement in driving capability of the driver IC and provision of a plurality of driver ICs have been promoted.

As the resolution is increased, stability of power supply of the driver IC that influences display quality is becoming important. Specifically, at a writing start timing of the voltage according to the designated gradation of the pixel, output of the driving circuit is lowered due to a drop in the power supply voltage, and in contrast, at a writing end timing of the voltage, the voltage increases. As a result, the power supply is not stabilized, and this leads to an adverse effect on the display quality in some cases.

In a case where an IC circuit is mounted on a flexible printed circuit board as a general double-sided wiring board, in order to stabilize the power supply, on an area where the IC circuit is mounted on a front surface of the double-sided wiring board, a ground pattern as a so-called solid pattern, which is entirely filled with copper foil, is formed (for example, JP-A-10-223997). Further, in JP-A-10-223997, a power supply pattern as a so-called solid pattern is formed on an area of a back surface of the double-sided wiring board that corresponds to the area, and electrostatic capacitance is increased with respect to the ground potential.

However, since the flexible printed circuit board to which the liquid crystal panel is adhered, is generally a single-sided board, a ground pattern and a power supply pattern as a solid pattern cannot be provided on both sides of the board, as in JP-A-10-223997. It is difficult to realize double-sided wiring of the flexible printed circuit board, and it is difficult to dispose a decoupling capacitor in the immediate vicinity of the driving circuit. In addition, these measures have disadvantages such as an increase in a manufacturing cost.

### SUMMARY

An advantage of some aspects of the invention is to provide an electro-optical device capable of performing high-resolution display and high-quality display by stabilizing power supply even in a case where a flexible printed circuit board as a single-sided wiring board is used, and an electronic apparatus including the electro-optical device.

According to an aspect of the invention, there is provided an electro-optical device including: an integrated circuit that supplies an image signal and a control signal to an electro-optical panel; and a flexible printed circuit board that includes a first connection terminal group which is provided on a wiring formation surface on which wirings are formed and includes control signal terminals electrically connected to a terminal for supplying the control signal in the integrated circuit, a second connection terminal group which is provided on the wiring formation surface and includes power supply connection terminals electrically connected to a power supply terminal or a ground terminal of the integrated circuit, and an adhesion surface which is provided between the first connection terminal group and the second connection terminal group and to which the integrated circuit is adhered via an adhesive, in which a wiring layer electrically connected to the power supply terminal or the ground terminal of the integrated circuit is formed on a surface of the integrated circuit that faces the adhesion surface, and in which a planar pattern electrically connected to the power supply connection terminals is formed on the adhesion surface of the flexible printed circuit board.

According to the aspect of the invention, on the surface of the integrated circuit that is adhered to the flexible printed circuit board, that is, on the surface facing the adhesion surface, the wiring layer electrically connected to the power supply terminal or the ground terminal of the integrated circuit is formed so as to uniformly spread. In addition, the planar pattern electrically connected to the power supply connection terminals is formed on the adhesion surface of the flexible printed circuit board. Therefore, in a state where the integrated circuit is adhered to the adhesion surface by the adhesive, the wiring layer which is connected to the power supply terminal or the ground terminal of the integrated circuit, and the planar pattern which is formed on the adhesion surface and is electrically connected to the power supply connection terminals, are disposed so as to face each other with the adhesive interposed therebetween. That is, by forming the planar pattern electrically connected to the power supply connection terminals on the adhesion surface, it is possible to form additional capacitance which is coupled to the wiring layer electrically connected to the power supply terminal or the ground terminal of the integrated circuit. Thus, even in a case where the single-sided flexible printed circuit board is used, it is possible to realize low impedance of the power supply terminal or the ground terminal of the integrated circuit and coupling of the additional capacitance to the wiring layer, and to improve stability of the power supply, without adding a decoupling capacitor element. Therefore, even in a case where a power supply voltage is changed at a timing of supplying the image signal from the integrated circuit to the pixel, it is possible to stabilize the power supply voltage in a short period. In addition, in this manner, since the power supply voltage can be stabilized, a writing time to the pixel can be also shortened, and display quality can be improved by preventing occurrence of display unevenness or the like.

In the electro-optical device according to the aspect, the wiring layer of the integrated circuit may be a wiring layer electrically connected to the ground terminal, and the planar pattern electrically connected to power supply terminals among the power supply connection terminals may be formed on the adhesion surface of the flexible printed circuit board. According to the aspect of the invention, in a state where the integrated circuit is adhered to the adhesion surface by the adhesive, the wiring layer which is connected to the ground terminal of the integrated circuit, and the planar pattern which is formed on the adhesion surface and is electrically connected to the power supply terminals among the power supply connection terminals, are disposed so as to face each other with the adhesive interposed therebetween. That is, by forming the planar pattern electrically connected to the power supply connection terminals on the adhesion surface, it is possible to form additional capacitance which is coupled to the wiring layer electrically connected to the ground terminal of the integrated circuit. Thus, even in a case where the single-sided flexible printed circuit board is used, it is possible to realize low impedance of the ground terminal of the integrated circuit and coupling of the additional capacitance to the wiring layer, and to improve stability of the power supply, without adding a decoupling capacitor element. Therefore, even in a case where a power supply voltage is changed at a timing of supplying the image signal from the integrated circuit to the pixel, it is possible to stabilize the power supply voltage in a short period. In addition, in this manner, since the power supply voltage can be stabilized, a writing time to the pixel can be also shortened, and display quality can be improved by preventing occurrence of display unevenness or the like.

In the electro-optical device according to the aspect, the planar pattern may be divided into a first planar pattern connected to analog power supply terminals among the power supply terminals, and a second planar pattern connected to digital power supply terminals among the power supply terminals. According to the aspect of the invention, it is possible to stabilize the analog power supply and the digital power supply. Thus, a writing time to the pixel can be also shortened, and display quality can be improved by preventing occurrence of display unevenness or the like.

In the electro-optical device according to the aspect, the wiring layer of the integrated circuit may be a wiring layer electrically connected to the power supply terminal, and the planar pattern electrically connected to ground terminals among the power supply connection terminals may be formed across the entire surface of the adhesion surface of the flexible printed circuit board. According to the aspect of the invention, in a state where the integrated circuit is adhered to the adhesion surface by the adhesive, the wiring layer which is connected to the power supply terminal of the integrated circuit, and the planar pattern which is formed on the adhesion surface and is electrically connected to the ground terminals among the power supply connection terminals, are disposed so as to face each other with the adhesive interposed therebetween. That is, by forming the planar pattern electrically connected to the ground terminals among the power supply connection terminals on the adhesion surface, it is possible to form additional capacitance which is coupled to the wiring layer electrically connected to the power supply terminal of the integrated circuit. Thus, even in a case where the single-sided flexible printed circuit board is used, it is possible to realize low impedance of the power supply terminal of the integrated circuit and coupling of the additional capacitance to the wiring layer, and to improve stability of the power supply, without adding a decoupling capacitor element. Therefore, even in a case where a power supply voltage is changed at a timing of supplying the image signal from the integrated circuit to the pixel, it is possible to stabilize the power supply voltage in a short period. In addition, in this manner, since the power supply voltage can be stabilized, a writing time to the pixel can be also shortened, and display quality can be improved by preventing occurrence of display unevenness or the like.

According to still another aspect of the invention, there is provided an electronic apparatus including the electro-optical device according to the aspect of the invention. The electronic apparatus is an electronic apparatus including the electro-optical device in which the power supply voltage is stabilized, a writing time to the pixel is shortened, and display quality is good without display unevenness or the like.

### BRIEF DESCRIPTION OF THE DRAWINGS

The invention will be described with reference to the accompanying drawings, wherein like numbers reference like elements.

FIG. 1 is an explanatory diagram of an electro-optical device according to a first embodiment of the invention.

FIG. 2 is a block diagram illustrating a configuration of the electro-optical device according to the first embodiment.

FIG. 3 is a circuit diagram illustrating a configuration of a pixel.

FIG. 4 is a plan view illustrating a TFT array substrate and components formed on the TFT array substrate when seen from a counter substrate.

FIG. 5 is a sectional view taken along a line V-V′ of FIG. 4.

FIG. 6 is a plan view illustrating a portion of a flexible printed circuit board.

FIG. 7 is a sectional view illustrating the periphery of an integrated circuit in a state where the driving integrated circuit is attached to the flexible printed circuit board.

FIG. 8 is a plan view illustrating a portion of a flexible printed circuit board according to a second embodiment of the invention.

FIG. 9 is an explanatory diagram illustrating an example of an electronic apparatus.

FIG. 10 is an explanatory diagram illustrating another example of an electronic apparatus.

FIG. 11 is an explanatory diagram illustrating still another example of an electronic apparatus.

### DESCRIPTION OF EXEMPLARY EMBODIMENTS

### First Embodiment

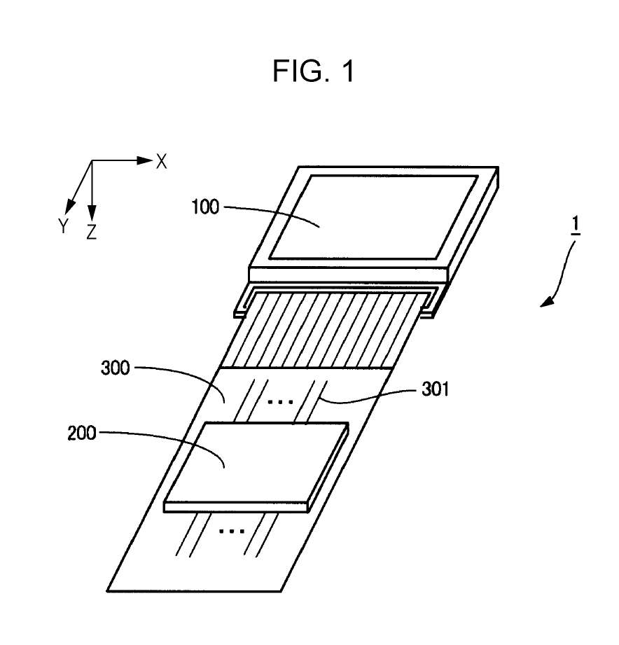

A first embodiment according to the invention will be described with reference to FIGS. 1 to 7. FIG. 1 is a diagram illustrating a configuration of a signal transmission system of an electro-optical device 1. As illustrated in FIG. 1, the electro-optical device 1 includes an electro-optical panel 100, a driving integrated circuit (driver IC) 200, and a flexible printed circuit board 300, and the electro-optical panel 100 is connected to the flexible printed circuit board 300 on which the driving integrated circuit 200 is mounted. The electro-optical panel 100 is connected to a board of a host CPU apparatus (not illustrated) via the flexible printed circuit board 300 and the driving integrated circuit 200. The driving integrated circuit 200 is a device that receives an image signal and various control signals for driving control from the host CPU apparatus via the flexible printed circuit board 300 and drives the electro-optical panel 100 via the flexible printed circuit board 300. The flexible printed circuit board 300 is a flexible printed circuits (FPC) board on which the driving integrated circuit 200 is mounted by a chip on film (COF) mounting structure. A plurality of wirings 301 are formed on the front surface of the flexible printed circuit board 300 that faces an upper direction of FIG. 1 (a direction opposite to the Z direction). The driving integrated circuit 200 is electrically and mechanically fixed to the flexible printed circuit board 300 by a COF mounting structure using a tape automated bonding (TAB) technology.

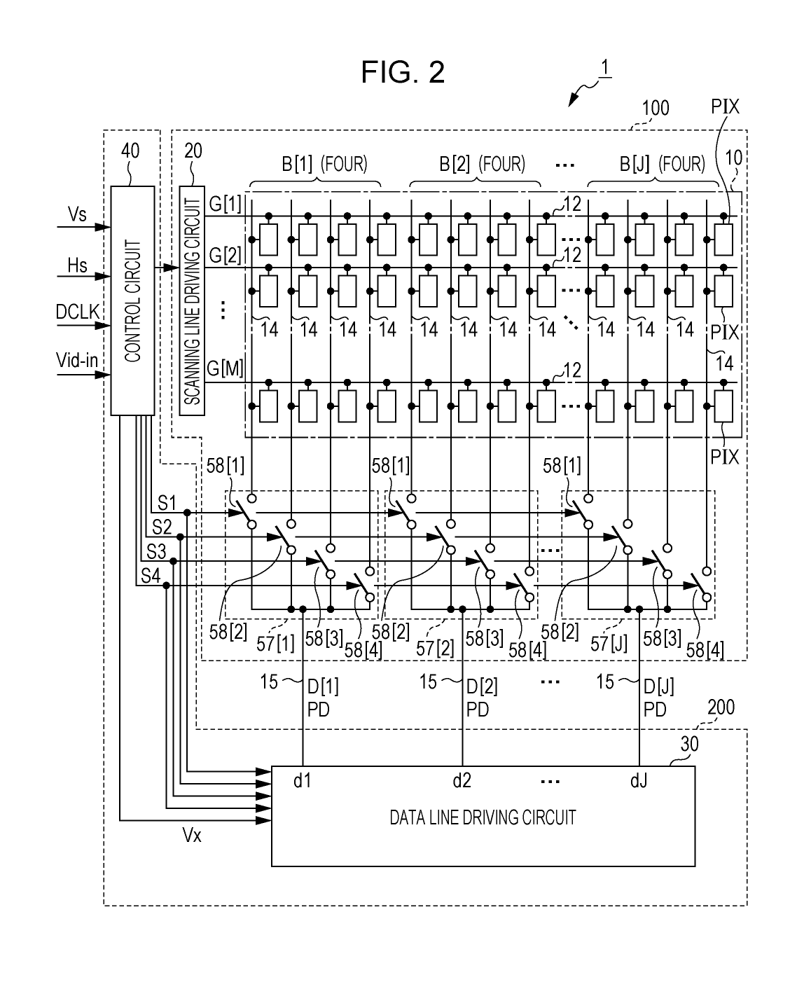

FIG. 2 is a block diagram illustrating configurations of the electro-optical panel 100 and the driving integrated circuit 200. As illustrated in FIG. 2, the electro-optical panel 100 includes a pixel unit 10, a scanning line driving circuit 20, and J demultiplexers 57[1] to 57[J] (J is a natural number). The driving integrated circuit 200 includes a data line driving circuit 30 and a control circuit 40.

In the pixel unit 10, M scanning lines 12 and N data lines 14 that intersect with each other are formed (M and N are natural numbers). A plurality of pixel circuits (pixels) PIX are provided corresponding to respective intersections between the respective scanning lines 12 and the respective data lines 14, and are arranged in a matrix shape of M rows in the longitudinal direction×N columns in the transverse direction.

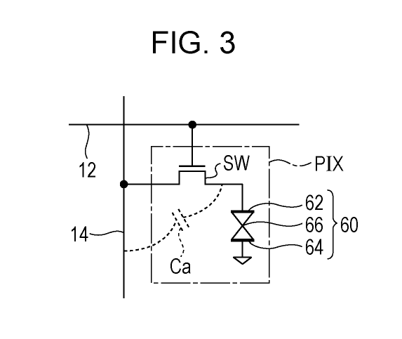

FIG. 3 is a circuit diagram of each pixel circuit PIX. As illustrated in FIG. 3, each pixel circuit PIX includes a liquid crystal element 60 and a switching element SW such as a TFT. In the present embodiment, a TFT is used as an example of the switching element SW. The liquid crystal element 60 is an electro-optical element that is configured with a pixel electrode 62 and a common electrode 64 which face each other and a liquid crystal 66 interposed between both electrodes. Transmittance (display gradation) of the liquid crystal 66 changes according to a voltage applied between the pixel electrode 62 and the common electrode 64. A configuration in which an auxiliary capacitor is connected to the liquid crystal element 60 in parallel, may be adopted. The switching element SW is configured with, for example, an N-channel type transistor of which the gate is connected to the scanning line 12. The switching element SW is provided between the liquid crystal element 60 and the data line 14, and controls electrical connection (conduction/non-conduction) between the liquid crystal element 60 and the data line 14. When a scanning signal G[m] is set to selection potential, the switching element SW of each pixel circuit PIX in the m-th row simultaneously transitions to an ON state (m is a natural number of 1 to M).

When the scanning line 12 corresponding to the pixel circuit PIX is selected and the switching element SW of the pixel circuit PIX is controlled to become an ON state, a voltage according to an image signal D[n] (n is a natural number from 1 to J) which is supplied from the data line 14 to the pixel circuit PIX, is applied to the liquid crystal element 60. As a result, transmittance of the liquid crystal 66 of the pixel circuit PIX is set to transmittance according to the image signal D[n]. When a light source (not illustrated) becomes an ON (turn-on) state and light is emitted from the light source, the light passes through the liquid crystal 66 of the liquid crystal element 60 included in the pixel circuit PIX, and proceeds toward an observer. That is, when the voltage according to the image signal D[n] is applied to the liquid crystal element 60 and the light source becomes an ON state, the pixel corresponding to the pixel circuit PIX displays gradation according to the image signal D[n].

After the voltage according to the image signal D[n] is applied to the liquid crystal element 60 of the pixel circuit PIX, when the switching element SW becomes an OFF state, ideally, the applied voltage corresponding to the image signal D[n] is held. Therefore, ideally, each pixel displays the gradation according to the image signal D[n] during a period from when the switching element SW becomes an ON state to when the switching element SW becomes an ON state next time.

As illustrated in FIG. 3, parasitic capacitance Ca is present between the data line 14 and the pixel electrode (or between the data line 14 and a wiring for electrically connecting the pixel electrode 62 and the switching element SW). For this reason, during a period for which the switching element SW is in an OFF state, there is a case where a change in potential of the data line 14 propagates to the pixel electrode 62 via the capacitance Ca and the applied voltage of the liquid crystal element 60 changes.

In addition, a common voltage LCCOM, which is a constant voltage, is supplied to the common electrode 64 via a common line (not illustrated). As the common voltage LCCOM, a voltage with a difference of approximately −0.5 V when the center voltage of an amplitude of the image signal D[n] is 0 V, is used. This is due to characteristics of the switching element SW and the like.

In the present embodiment, in order to prevent so-called ghosting, polarity inversion driving that inverts polarity of the voltage applied to the liquid crystal element 60 at a predetermined period, is adopted. In this example, a level of the image signal D[n] supplied to the pixel circuit PIX via the data line 14 is inverted with respect to the center voltage of the image signal D[n], for each unit period. The unit period is a period of an operation as one unit that drives the pixel circuit PIX. In this example, the unit period is the vertical scanning period V. Here, the unit period may be arbitrarily set, and for example, may be a natural number times the vertical scanning period V. In the present embodiment, a case where the voltage of the image signal D[n] becomes a higher voltage than the center voltage thereof is represented as positive polarity, and a case where the voltage of the image signal D[n] becomes a lower voltage than the center voltage thereof is represented as negative polarity.

Returning to FIG. 2, a vertical synchronization signal Vs that defines a vertical scanning period V, a horizontal synchronization signal Hs that defines a horizontal scanning period H, a dot clock signal DCLK, and a video signal Vid-in are input to the control circuit 40 from an external host CPU apparatus (not illustrated). The control circuit 40 performs synchronization control of the scanning line driving circuit 20 and the data line driving circuit 30 based on the signals. Under the synchronization control, the scanning line driving circuit 20 and the data line driving circuit 30 control display of the pixel unit 10 in cooperation with each other.

Typically, display data constituting one display screen is processed in a frame unit, and the processing period is one frame period (1F). The frame period F corresponds to the vertical scanning period V in a case where one display screen is formed by one vertical scanning.

The scanning line driving circuit 20 outputs scanning signals G[1] to G[M] to the respective M scanning lines 12. In response to output of the horizontal synchronization signal Hs from the control circuit 40, the scanning line driving circuit 20 sequentially sets the scanning signals G[1] to G[M] for the respective scanning lines 12, to an active level, for one horizontal scanning period (1H), within the vertical scanning period V.

Here, during a period for which the scanning signal G[m] corresponding to the m-th row is set to an active level and the scanning line corresponding to the m-th row is selected, the respective switching elements SW of the N pixel circuits PIX in the m-th row become an ON state. As a result, the respective N data lines 14 are electrically connected to the respective pixel electrodes 62 of the N pixel circuits PIX in the m-th row via the respective switching elements SW.

In the present embodiment, the N data lines 14 in the pixel unit 10 are divided into J wiring blocks B[1] to B[J] (J=N/4) each with four data lines 14 as a unit that are adjacent to each other. In other words, the data lines 14 are grouped for each wiring block B. The demultiplexers 57[1] to 57[J] correspond to the J wiring blocks B[1] to B[J], respectively. As will be described later, in the present embodiment, since the data lines 14 are divided into units each with four data lines 14, the image signal D[n] includes a data voltage for four pixels.

Each demultiplexer 57[j] is configured with four switches 58[1] to 58[4] (j is a natural number from 1 to J). In each demultiplexer 57[j], one contact of each of the four switches 58[1] to 58[4] is commonly connected to a point. The point, which is commonly connected to the one contact of each of the four switches 58[1] to 58[4] in each demultiplexer 57[j], is connected to each of J VID signal lines 15. The J VID signal lines 15 are connected to the data line driving circuit 30 of the driving integrated circuit 200 via the flexible printed circuit board 300.

In addition, in each demultiplexer 57[j], the other contact of each of the four switches 58[1] to 58[4] is connected to each of the four data lines 14 constituting the wiring block B[j] corresponding to the demultiplexer 57[j].

ON/OFF of each of the four switches 58[1] to 58[4] in each demultiplexer 57[j] is switched by each of four selection signals S1 to S4. The four selection signals S1 to S4 are supplied from the control circuit 40 of the driving integrated circuit 200 via the flexible printed circuit board 300. Here, for example, in a case where one selection signal S1 becomes an active level and the other three selection signals S2 to S4 become a non-active level, the J switches 58[1] belonging to each demultiplexer 57[j] become an ON state. Thus, each demultiplexer 57[j] outputs each of the image signals D[1] to D[J] on the J VID signal lines 15, to the first data line 14 of each of the wiring blocks B[1] to B[J]. Thereafter, in the same manner, each demultiplexer 57[j] outputs each of the image signals D[1] to D[J] on the J VID signal lines 15, to the second, third, and fourth data lines 14 of each of the wiring blocks B[1] to B[J].

The control circuit 40 generates various control signals, and controls each unit in synchronization with the vertical synchronization signal Vs, the horizontal synchronization signal Hs, and the dot clock signal DCLK. As will be described in detail later, the control circuit 40 outputs an analog data signal Vx by processing the digital video signal Vid-in supplied from the host CPU apparatus.

The video signal Vid-in is digital data for designating a gradation level of each pixel in the electro-optical panel 100, and is supplied in a scanning order according to the vertical synchronization signal Vs, the horizontal synchronization signal Hs, and the dot clock signal DCLK.

The data line driving circuit 30 outputs data to be supplied for each row of the pixels to which data is written, to the data lines 14, in cooperation with the scanning line driving circuit 20. The data line driving circuit 30 generates a latch signal based on the selection signals S1 to S4 output from the control circuit 40, and sequentially latches the data signals Vx supplied as serial data. The data signals Vx are grouped as time-series data every four pixels. In addition, the data line driving circuit 30 is provided with a digital to analog (D/A) conversion circuit as a D/A conversion unit, and a voltage amplification unit. The D/A conversion circuit performs D/A conversion based on the grouped digital data and an analog voltage generated by an analog voltage generation circuit (not illustrated), and the voltage amplification unit generates a voltage as analog data by performing amplification. Thus, the data signals Vx which are arranged in a time-series manner in units of four pixels, are also converted into predetermined data voltages. The data voltages for four pixels are supplied from output terminals d1 to dJ to the VID signal lines 15, as image signals D[1] to D[J].

In each demultiplexer 57[j], conduction (ON/OFF) of each of the switches 58[1] to 58[4] is controlled by each of the selection signals S1 to S4 output from the control circuit 40, and each of the switches 58[1] to 58[4] becomes an ON state at a predetermined timing. During a period for which the precharge signal is applied, conduction of each of the switches 58[1] to 58[4] is controlled by each of the selection signals S1 to S4 output from the control circuit 40, and the switches 58[1] to 58[4] of the demultiplexer 57[j] simultaneously become an ON state.

Thus, in one horizontal scanning period (1H), the data voltage D[n] for four pixels that is supplied to each VID signal line 15, is output to the data lines 14 in a time-series manner by the switches 58[1] to 58[4].

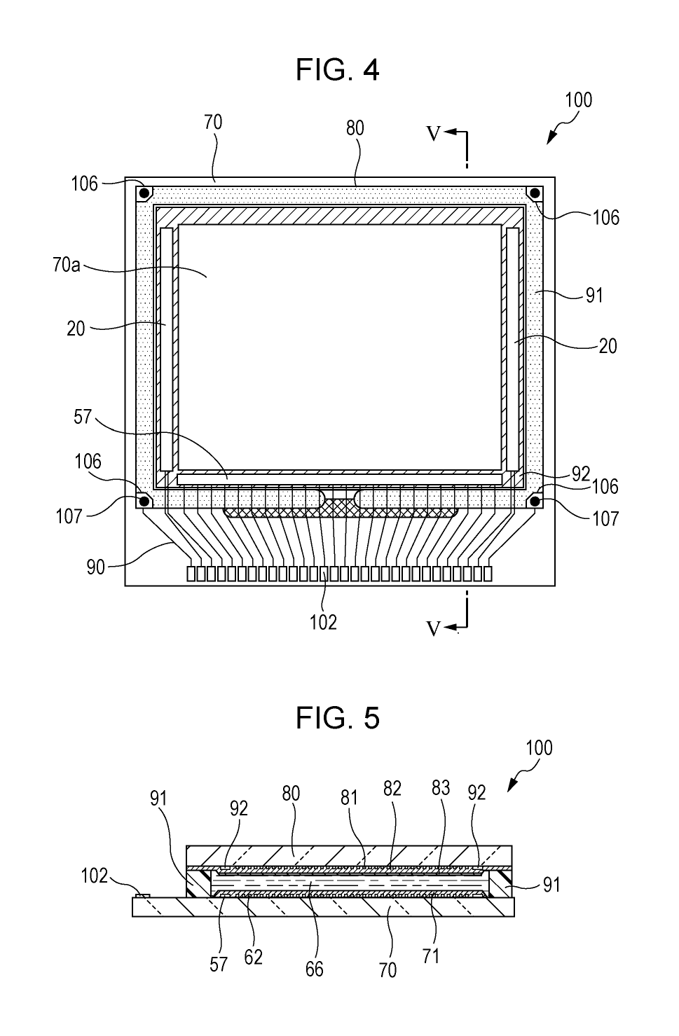

Next, the electro-optical panel 100 will be described with reference to FIGS. 4 and 5. FIG. 4 is a plan view illustrating a TFT array substrate 70 and components formed on the TFT array substrate 70 when seen from a counter substrate 80, and FIG. 5 is a sectional view taken along a line V-V′ of FIG. 4.

In FIGS. 4 and 5, in the electro-optical panel 100 according to the present embodiment, the TFT array substrate 70 on which TFT switching elements SW are arranged is disposed so as to face the counter substrate 80. The TFT array substrate 70 is made of, for example, a transparent substrate such as a quartz substrate or a glass substrate, or a silicon substrate, and the counter substrate 80 is made of, for example, a transparent substrate such as a quartz substrate or a glass substrate. The liquid crystal 66 is sealed between the TFT array substrate 70 and the counter substrate 80. The TFT array substrate 70 and the counter substrate 80 are adhered to each other by sealing members 91 which are provided in a sealing area positioned around an image display area 70a corresponding to the pixel unit 10 in which the plurality of pixels PIX are provided.

The sealing member 91 is made of, for example, a ultraviolet-curable resin, a thermosetting resin, a ultraviolet-curable/thermosetting resin, or the like, which is used for bonding both substrates, and is cured by ultraviolet ray irradiation, heating, or the like after being applied on the TFT array substrate 70 in a manufacturing process. In the sealing member 91, a gap material such as glass fiber or glass beads for maintaining a distance between the TFT array substrate 70 and the counter substrate 80 to a predetermined value, is dispersed. In addition to mix the gap material into the sealing member 91, or instead of mixing the gap material into the sealing member 91, the gap material may be disposed in the image display area 70a or a peripheral area positioned around the image display area 70a.

In FIG. 4, a frame-shaped light shielding film 92 having a light shielding property that defines a frame area of the image display area 70a, is provided on the counter substrate 80 side, in parallel with the inside of the sealing area in which the sealing member 91 is disposed. On the other hand, a portion or the entire portion of the frame-shaped light shielding film 92 may be provided on the TFT array substrate 70 side, as a built-in light shielding film.

External circuit connection terminals 102 are provided in an area among the peripheral area that is positioned outside the sealing area in which the sealing member 91 is disposed, along one side of the TFT array substrate 70. A demultiplexer 57 is provided inside the sealing area along the one side so as to be covered by the frame-shaped light shielding film 92. The scanning line driving circuit 20 is provided inside the sealing area along two sides adjacent to the one side so as to be covered by the frame-shaped light shielding film 92. The external circuit connection terminals 102 includes input terminals for the selection signals S1 to S4, the image signals D[1] to D[J], and power supply, and a ground terminal.

On the TFT array substrate 70, upper and lower conduction terminals 106 for connecting the two substrates to each other using upper and lower conduction members 107 are disposed in areas facing four corner portions of the counter substrate 80. Thus, electrical conduction between the TFT array substrate 70 and the counter substrate 80 can be made. In addition, leading wirings 90 for electrical connection between the external circuit connection terminals 102 and the scanning line driving circuit 20 and upper and lower conduction terminals 106, are formed.

In FIG. 5, on the TFT array substrate 70, a stacked structure in which the switching elements SW and wirings such as the scanning lines 12 and the data lines 14 are formed, is formed. Although a detailed configuration of the stacked structure is not illustrated in FIG. 5, the pixel electrode 62 made of a transparent material such as indium tin oxide (ITO), is formed in an island shape with a predetermined pattern for each pixel, on the stacked structure.

The pixel electrode 62 is formed in the image display area 70a on the TFT array substrate 70 so as to face the counter electrode 82 to be described later. An alignment film 71 is formed on a front surface of the TFT array substrate 70 that faces the liquid crystal 66, that is, on the pixel electrode 62, so as to cover the pixel electrode 62.

A light shielding film 81 is formed on a surface of the counter substrate 80 that faces the TFT array substrate 70. The light shielding film 81 is formed, for example, in a lattice shape when seen in a plan view on the facing surface of the counter substrate 80. In the counter substrate 80, a non-opening area is defined by the light shielding film 81, and an area partitioned by the light shielding film 81 is an opening area through which light emitted from a projector lamp or a direct-vision type backlight is transmitted. On the other hand, the light shielding film 81 may be formed in a stripe shape, and the non-opening area may be defined by the light shielding film 81 and various components such as the data lines provided on the TFT array substrate 70 side.

Counter electrodes 82 made of a transparent material such as ITO are formed on the light shielding film 81 so as to face the plurality of pixel electrodes 62. In order to perform color display in the image display area 70a, on the light shielding film 81, a color filter (not illustrated in FIG. 5) may be formed in an area including the opening area and a portion of the non-opening area. An alignment film 83 is formed on a surface of the counter electrode 82 that faces the counter substrate 80.

On the TFT array substrate 70 illustrated in FIGS. 4 and 5, in addition to the scanning line driving circuit 20, the demultiplexer 57, and the like, a precharge circuit which supplies a precharge signal having a predetermined voltage level to each of the plurality of data lines 14 before supply of the image signals, may be formed. In addition, an inspection circuit or the like for inspecting quality, defects, or the like of the liquid crystal device in manufacturing or shipping, may be formed.

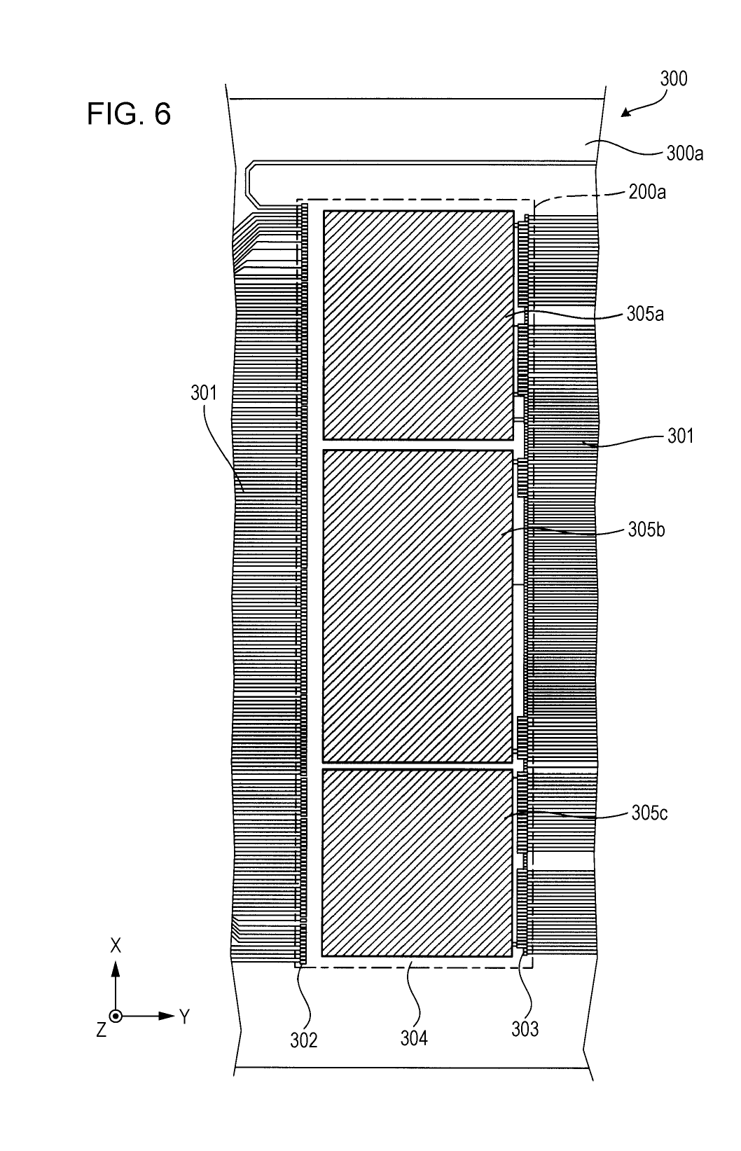

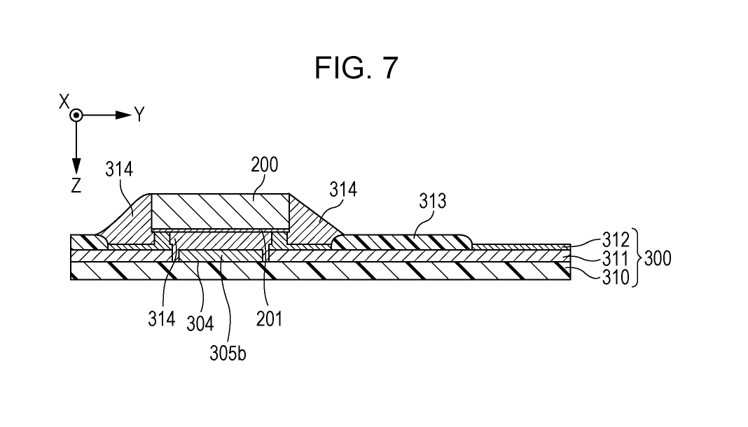

Next, the flexible printed circuit board 300 according to the present embodiment will be described in detail with reference to FIGS. 6 and 7. FIG. 6 is a plan view illustrating a portion of the flexible printed circuit board 300, and FIG. 7 is a sectional view illustrating the periphery of the driving integrated circuit 200 in a state where the driving integrated circuit 200 is mounted on the flexible printed circuit board 300.

FIG. 6 is a plan view illustrating a portion of the flexible printed circuit board 300 to which the driving integrated circuit 200 is mounted and the periphery of the portion when seen from the Z direction illustrated in FIG. 1, and illustrates a cut portion of the flexible printed circuit board 300. As illustrated in FIG. 6, a plurality of wirings 301 are formed on a wiring formation surface 300a of the flexible printed circuit board 300. Among the plurality of wirings 301, control signal wirings and power supply wirings respectively include control signal connection terminals and power supply connection terminals at end portions thereof. The flexible printed circuit board 300 includes a first connection terminal group 302 including control signal connection terminals for supplying control signals to the driving integrated circuit 200, on the wiring formation surface 300a on which the wirings 301 are formed. The control signal connection terminal is electrically connected to a terminal of the driving integrated circuit 200. In addition, the flexible printed circuit board 300 includes a second connection terminal group 303 including power supply connection terminals electrically connected to a power supply terminal or a ground terminal of the driving integrated circuit 200, on the wiring formation surface 300a on which the wirings 301 are formed. Further, the flexible printed circuit board 300 is provided with an adhesion surface 304 which is provided between the first connection terminal group 302 and the second connection terminal group 303 and to which the driving integrated circuit 200 is adhered via an adhesive. In FIG. 6, an adhesion position 200a to which the driving integrated circuit 200 is adhered, is illustrated by a one-dot chain line.

On the adhesion surface 304 of the flexible printed circuit board 300, planar power supply patterns 305a, 305b, and 305c electrically connected to the power supply terminals among the power supply connection terminals of the second connection terminal group 303, are formed. The power supply patterns 305a, 305b, and 305c are formed as a so-called solid pattern. The power supply patterns 305a, 305b, and 306c are divided and formed, and the power supply patterns 305a and 305c as a first planar pattern are connected to analog power supply terminals. In addition, the power supply pattern 305b as a second planar pattern is connected to digital power supply terminals. The planar pattern may be a pattern including a portion having a width wider than a wiring width of each wiring 301. On the other hand, in order to form additional capacitance to be described later, it is effective that the planar pattern has a size along the adhesion position 200a to which the driving integrated circuit 200 is adhered. In FIG. 6, three different planar patterns with a rectangular shape are illustrated.

FIG. 7 is a sectional view of the flexible printed circuit board 300 to which the driving integrated circuit 200 is adhered, in a direction along the Y direction illustrated in FIG. 1.

As illustrated in FIG. 7, on the surface of the driving integrated circuit 200 that is adhered to the flexible printed circuit board 300, that is, on the surface facing the adhesion surface 304 of the flexible printed circuit board 300, a wiring layer 201 electrically connected to the ground terminal of the driving integrated circuit 200 is formed so as to uniformly spread.

The flexible printed circuit board 300 is configured with a base 310 made of polyimide or the like, a copper foil 311 formed on the base 310, and an Au plating 312 for forming a first connection terminal group 302, and a second connection terminal group 303, and wirings 301. In addition, a solder resist 313 is appropriately provided on the copper foil 311.

The driving integrated circuit 200 is adhered to an adhesion surface 304 of the flexible printed circuit board 300 by an underfill 314 as an adhesive having a predetermined dielectric constant. The underfill 314 is provided so as to cover a connection portion between a terminal such as a ground terminal of the driving integrated circuit 200 and the wiring 301.

As illustrated in FIG. 7, in a state where the driving integrated circuit 200 is adhered to the adhesion surface 304 of the flexible printed circuit board 300 by the underfill 314, the wiring layer 201 of the driving integrated circuit 200 and the power supply patterns 305a, 305b, and 305c as the solid pattern formed on the adhesion surface 304, are disposed so as to face each other with the underfill 314 interposed therebetween. Thus, in the present embodiment, by forming the power supply patterns 305a, 305b, and 305c of the flexible printed circuit board 300 in a so-called solid pattern, it is possible to form additional capacitance which is coupled to the wiring layer 201 electrically connected to the ground terminal of the driving integrated circuit 200.

As a result, in the present embodiment, even in a case where the flexible printed circuit board 300 as a single-sided wiring board is used, it is possible to realize low impedance of the ground terminal of the integrated circuit 200 and coupling of the additional capacitance to the wiring layer 201, and to improve stability of the power supply, without adding a decoupling capacitor element. Therefore, even in a case where a power supply voltage is changed at a timing of supplying the image signal D[n] from the data line driving circuit 30 to the pixel PIX, it is possible to stabilize the power supply voltage in a short period. In addition, in this manner, since the power supply voltage can be stabilized, a writing time to the pixel PIX can be also shortened, and display quality can be improved by preventing occurrence of display unevenness or the like.

### Second Embodiment

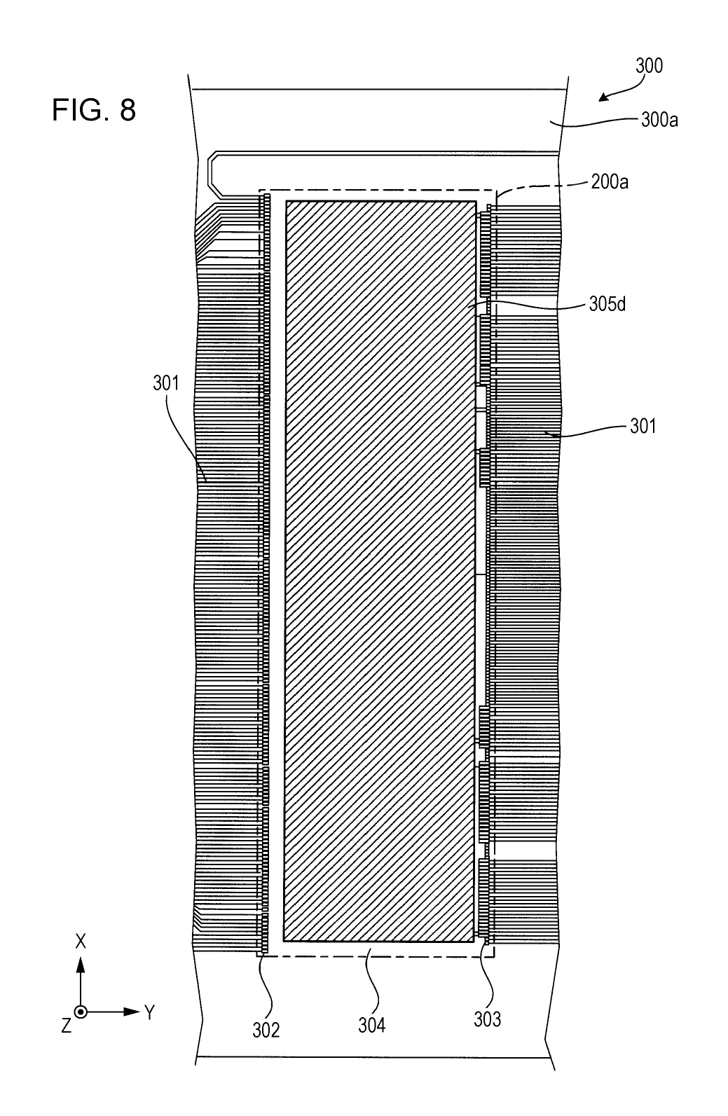

Next, a second embodiment according to the invention will be described with reference to FIG. 8. FIG. 8 is a plan view illustrating a portion of the flexible printed circuit board 300 according to the present embodiment.

In the present embodiment, on the adhesion surface 304 of the flexible printed circuit board 300, a planar ground pattern 305d, which is electrically connected to the ground terminals among the power supply connection terminals included in the second connection terminal group 303, is formed across the entire surface of the adhesion surface 304 excluding an area at which the ground terminals are disposed. The ground pattern is formed as a so-called solid pattern.

In addition, in the present embodiment, although not illustrated, on the surface of the integrated circuit 200 that is adhered to the flexible printed circuit board 300, that is, on the surface facing the adhesion surface 304 of the flexible printed circuit board 300, the wiring layer 201 electrically connected to the power supply terminal of the driving integrated circuit 200 is formed.

Therefore, even in the present embodiment, in a state where the driving integrated circuit 200 is adhered to the adhesion surface 304 by the underfill 314, the wiring layer 201 of the driving integrated circuit 200 that is connected to the power supply terminals and the ground pattern 305d as the solid pattern that is formed on the adhesion surface 304 of the flexible printed circuit board 300, are disposed so as to face each other with the underfill 314 interposed therebetween. Thus, in the present embodiment, by forming the ground pattern 305d of the flexible printed circuit board 300 in a so-called solid pattern, it is possible to form additional capacitance which is coupled to the wiring layer 201 electrically connected to the power supply terminal of the driving integrated circuit 200.

As a result, even in the present embodiment, even in a case where the single-sided flexible printed circuit board 300 is used, it is possible to realize low impedance of the ground terminal of the driving integrated circuit 200 and coupling of the additional capacitance to the wiring layer 201, and to improve stability of the power supply, without adding a decoupling capacitor element. Therefore, even in a case where a power supply voltage is changed at a timing of supplying the image signal D[n] from the data line driving circuit 30 to the pixel PIX, it is possible to stabilize the power supply voltage in a short period. In addition, in this manner, since the power supply voltage can be stabilized, a writing time to the pixel PIX can be also shortened, and display quality can be improved by preventing occurrence of display unevenness or the like.

### MODIFICATION EXAMPLE

The invention is not limited to the above-described embodiment, and for example, various modifications to be described below may be made. In addition, it goes without saying that each embodiment and each modification example may be appropriately combined with each other.

### MODIFICATION EXAMPLE 1

In the first embodiment, although the power supply patterns as the solid pattern that are formed on the adhesion surface 304 of the flexible printed circuit board 300 are divided into three, the invention is not limited to the aspect. The number of division of the power supply patterns or a method of division of the power supply patterns may be appropriately changed in accordance with layout of the driving integrated circuit 200.

### MODIFICATION EXAMPLE 2

In the above-described embodiment, although the liquid crystal is used as an example of an electro-optical material, the invention can also be applied to an electro-optical device using an electro-optical material other than the liquid crystal. The electro-optical material is a material of which the optical properties such as transmittance and luminance change by supply of an electric signal (current signal or voltage signal). For example, the invention can also be applied to a display panel using a light-emitting element such as an organic electroluminescent (EL), an inorganic EL, or a light-emitting polymer, as in the above-described embodiment. The invention can also be applied to an electrophoretic display panel using a microcapsule as an electro-optical material that includes a colored liquid and white particles dispersed in the liquid, as in the above-described embodiment. In addition, the invention can also be applied to a twisted ball display panel using a twist ball as an electro-optical material that is painted in different colors for each area with different polarity, as in the above-described embodiment. The invention can also be applied to various electro-optical devices such as a toner display panel using a black toner as an electro-optical material, or a plasma display panel using high-pressure gas such as helium or neon as an electro-optical material, as in the above-described embodiment.

### APPLICATION EXAMPLE

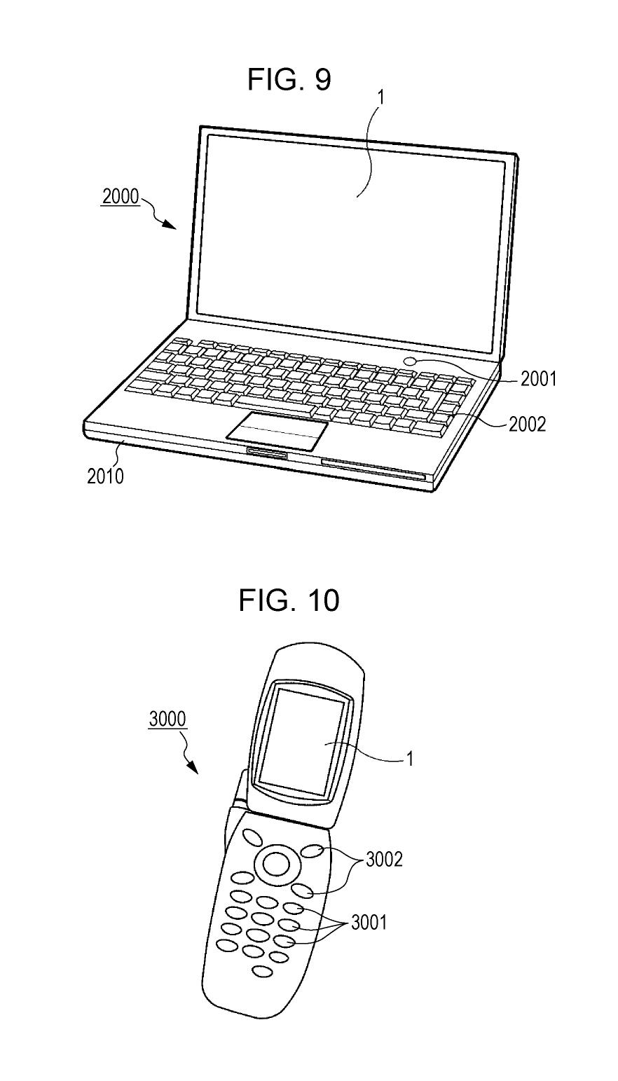

The invention can be used for various electronic apparatuses. FIGS. 9 to 11 illustrate specific forms of electronic apparatuses to which the invention is applied.

FIG. 9 is a perspective view of a portable personal computer to which an electro-optical device is adopted. The personal computer 2000 includes an electro-optical device 1 for displaying various images, and a main body unit 2010 on which a power supply switch 2001 and a keyboard 2002 are mounted.

FIG. 10 is a perspective view of a mobile phone. A mobile phone 3000 includes a plurality of operation buttons 3001 and scroll buttons 3002, and an electro-optical device 1 for displaying various images. When the scroll button 3002 is operated, a screen displayed on the electro-optical device 1 is scrolled. The invention can also be applied to such a mobile phone.

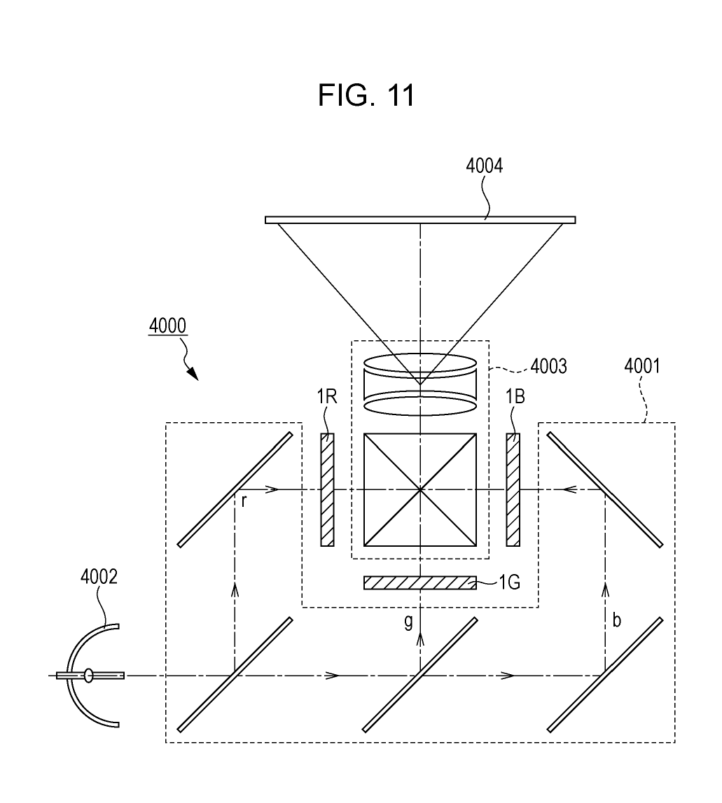

FIG. 11 is a schematic diagram illustrating a configuration of a projection type display apparatus (three-plate type projector) 4000 to which the electro-optical device is adopted. The projection type display apparatus 4000 includes three electro-optical devices 1 (1R, 1G, and 1B) corresponding to each of display colors R, G, and B different from each other. An illumination optical system 4001 supplies red components r of light emitted from an illumination device (light source) 4002 to the electro-optical device 1R, supplies green components g of the light to the electro-optical device 1G, and supplies blue components b of the light to the electro-optical device 1B. Each of the electro-optical devices 1 functions as an optical modulator (light valve) that modulates monochromatic light supplied from the illumination optical system 4001 according to the display image. A projection optical system 4003 combines the light emitted from the respective electro-optical devices 1, and projects the combined light on a projection surface 4004. The invention can also be applied to such a liquid crystal projector.

The electronic apparatuses to which the invention is applied include a personal digital assistants (PDA), in addition to the apparatuses illustrated in FIG. 1, and FIGS. 9 to 11. Further, the electronic apparatuses include a digital still camera, a television, a video camera, a car navigation apparatus, an in-vehicle display apparatus (instrument panel), an electronic organizer, an electronic paper, a calculator, a word processor, a workstation, a video phone, and a POS terminal. Furthermore, the electronic apparatuses include a printer, a scanner, a copier, a video player, an apparatus including a touch panel, and the like.

This application claims priority to Japan Patent Application No. 2016-190775 filed Sep. 29, 2016, the entire disclosures of which are hereby incorporated by reference in their entireties.

What is claimed is:

1. An electro-optical device comprising:
an integrated circuit that supplies an image signal and a control signal to an electro-optical panel; and
a flexible printed circuit board that includes a first connection terminal group which is provided on a wiring formation surface on which wirings are formed and includes control signal terminals electrically connected to a terminal for supplying the control signal in the integrated circuit, a second connection terminal group which is provided on the wiring formation surface and includes power supply connection terminals electrically connected to a power supply terminal or a ground terminal of the integrated circuit, and an adhesion surface which is provided between the first connection terminal group and the second connection terminal group and to which the integrated circuit is adhered via an adhesive,
wherein a wiring layer electrically connected to the power supply terminal or the ground terminal of the integrated circuit is formed on a surface of the integrated circuit that faces the adhesion surface, and
wherein a planar pattern electrically connected to the power supply connection terminals is formed on the adhesion surface of the flexible printed circuit board.

2. The electro-optical device according to claim 1,
wherein the wiring layer of the integrated circuit is a wiring layer electrically connected to the ground terminal, and
wherein the planar pattern electrically connected to power supply terminals among the power supply connection terminals is formed on the adhesion surface of the flexible printed circuit board.

3. The electro-optical device according to claim 2,
wherein the planar pattern is divided into a first planar pattern connected to analog power supply terminals among the power supply terminals, and a second planar pattern connected to digital power supply terminals among the power supply terminals.

4. The electro-optical device according to claim 1,
wherein the wiring layer of the integrated circuit is a wiring layer electrically connected to the power supply terminal, and
wherein the planar pattern electrically connected to ground terminals among the power supply connection terminals is formed across the entire surface of the adhesion surface of the flexible printed circuit board.

5. An electronic apparatus comprising:
the electro-optical device according to claim 1.

6. An electro-optical device comprising:
an electro-optical panel;
a flexible printed circuit board that is connected to the electro-optical panel and includes a first potential wiring, a second potential wiring, a first terminal connected to the first potential wiring, and a second terminal connected to the second potential wiring; and
an integrated circuit that is disposed on the flexible printed circuit board and includes a third terminal connected to the first terminal and a fourth terminal connected to the second terminal,
wherein the integrated circuit includes a first conductive pattern that is connected to the third terminal and includes a first planar portion overlapping with the flexible printed circuit board, and
wherein the flexible printed circuit board includes a second conductive pattern that is connected to the fourth terminal and includes a second planar portion overlapping with the first planar portion.

7. The electro-optical device according to claim 6,
wherein the first terminal is a ground terminal, and
wherein the second terminal is a power supply terminal.

8. The electro-optical device according to claim 6,
wherein the first terminal is a power supply terminal, and
wherein the second terminal is a ground terminal.

9. An electro-optical device comprising:
an electro-optical panel;
a flexible printed circuit board that is connected to the electro-optical panel and includes a first potential wiring, a second potential wiring, a third potential wiring, a first terminal connected to the first potential wiring, a second terminal connected to the second potential wiring, and a third terminal connected to the third potential wiring; and
an integrated circuit that is disposed on the flexible printed circuit board and includes a fourth terminal connected to the first terminal, a fifth terminal connected to the second terminal, and a sixth terminal connected to the third terminal,
wherein the integrated circuit includes
a first conductive pattern that is connected to the fourth terminal and includes a first planar portion overlapping with the flexible printed circuit board, and
a second conductive pattern that is connected to the fifth terminal and includes a second planar portion overlapping with the flexible printed circuit board, and
wherein the flexible printed circuit board includes
a third conductive pattern that is connected to the third terminal and includes a third planar portion overlapping with the first planar portion and the second planar portion.

10. The electro-optical device according to claim 9,
wherein the first terminal is an analog power supply terminal,
wherein the second terminal is a digital power supply terminal, and
wherein the third terminal is a ground terminal.

11. An electro-optical device comprising:
an electro-optical panel;
a flexible printed circuit board that is connected to the electro-optical panel and includes a first potential wiring, a second potential wiring, a third potential wiring, a first terminal connected to the first potential wiring, a second terminal connected to the second potential wiring, and a third terminal connected to the third potential wiring; and
an integrated circuit that is disposed on the flexible printed circuit board and includes a fourth terminal connected to the first terminal, a fifth terminal connected to the second terminal, and a sixth terminal connected to the third terminal,
wherein the flexible printed circuit board includes
a first conductive pattern that is connected to the first terminal and includes a first planar portion overlapping with the integrated circuit, and
a second conductive pattern that is connected to the second terminal and includes a second planar portion overlapping with the integrated circuit, and
wherein the integrated circuit includes
a third conductive pattern that is connected to the sixth terminal and includes a third planar portion overlapping with the first planar portion and the second planar portion.

12. The electro-optical device according to claim 11,
wherein the first terminal is an analog power supply terminal,
wherein the second terminal is a digital power supply terminal, and
wherein the third terminal is a ground terminal.

13. An electronic apparatus comprising:
the electro-optical device according to claim 6.

14. An electronic apparatus comprising:
the electro-optical device according to claim 9.

15. An electronic apparatus comprising:
the electro-optical device according to claim 11.
